(19) United States
(12) Patent Application Publication
(10) Pub. No.: US 2012/0235729 A1
(43) Pub. Date: Sep. 20, 2012

(54) INTEGRATED DEVICE AND METHOD OF REDUCING VOLTAGE DROPS ON A SUPPLY DISTRIBUTION METAL PATH OF A DEVICE

(75) Inventors: Giuseppe CONTI, Pedara (IT); Lorenzo LEONE, Scordia (IT)

(73) Assignee: STMICROELECTRONICS S.R.L., Agrate Brianza (IT)

(21) Appl. No.: 13/421,827

(22) Filed: Mar. 15, 2012

(30) Foreign Application Priority Data
Mar. 15, 2011 (IT) MI2011A000403

(51) Int. Cl. H03K 17/00

(52) U.S. Cl. 327/407

(57) ABSTRACT

An embodiment of an integrated circuit includes first and second pads, a supply conductor, and a selection circuit. The first pad is coupled to the supply conductor, and the selection circuit is configurable to couple the second pad to the supply conductor. For example, in a low-pin-count integrated circuit, one may select the second pad to be an input/output pad under normal-power conditions, and to be a supply pad under high-power conditions to reduce the voltage drop along the supply conductor.

### PRIORITY CLAIM

The instant application claims priority to Italian Patent Application No. MI2011A000403, filed Mar. 15, 2011, which application is incorporated herein by reference in its entirety.

### TECHNICAL FIELD

This disclosure relates in general to integrated circuits, and in particular to a packaged device having an array of input/output cells along its perimeter and a supply distribution metal path, where the packaged device is supplied through a single one, or a limited number of, spaced pads, and a related method of reducing voltage drops on a supply-distribution metal path of a device.

### BACKGROUND

Low-pin-count devices enjoy success because of their reduced number of input/output pads. A basic view of a printed circuit board PCB with a low-pin-count packaged device is shown in FIG. 1.

Typically, low-pin-count devices may have a single supply pad VDDIO and a number of input/output cells each containing a general-purpose input/output circuit (GPIO) coupled to a respective input/output pad. The supply voltage VDD, that, for example, may be of 3.3V, is internally distributed to all internal circuits through a supply-distribution metal path, that may be, for example, a supply metal ring or a metal grid that has a distributed parasitic resistance Rpg.

In the ensuing description, reference is made to the case in which the supply-distribution metal path is a ring surrounding the core of the circuit, though the same considerations hold mutatis mutandis if the metal distribution path is a grid.

The voltage drop along the supply metal ring, the maximum value of which in general depends on the functioning of the IO circuits and may be attained, for example, in correspondence of the farthest spot on the supply metal ring, and often “diametrically” opposite to a single supply pad VDDIO location, is a design constraint of low-pin-count devices, and depends upon the different current absorptions of the internal circuits and upon their distance from the supply pad(s) of the packaged device.

Low-pin-count devices have few supply pads and often only one supply pad (as shown by way of example in FIG. 1), thus the voltage drop along the supply metal ring may be significant, and the voltage effectively supplied to circuits coupled relatively far from the supply pad VDDIO may become too low to ensure their correct functioning. On the other hand, increasing the number of supply pads would be at the expense of the number of GPIO circuits that may be realized, and thus of the functions of the device.

For this reason, currents delivered/absorbed by the GPIOs are carefully designed (limited), and this is often a severe design constraint of low-pin-count devices.

### SUMMARY

Studies carried out have demonstrated an economical feasibility of having general purpose circuits of low-pin-count packaged integrated devices adapted to be effectively configured by users for injecting an auxiliary current on the supply-distribution metal path of the device, in order to supply, at a satisfactory voltage, circuits of the device that may occasionally or often absorb a current in excess of the nominal maximum design current that may be absorbed from the supply rail of the device.

Therefore, an embodiment of a packaged device of this disclosure, having at least an input/output cell of such a modified circuit topology, may be configured by users such to use the modified input/output cell as a normal signal input/output circuit or, when needed, to inject an auxiliary current on the supply-distribution metal path of the device, simply by changing its circuital configuration. In the last case, the number of pins usable as input/output of signals is reduced, but the packaged device may be relieved of design constraints of prior-art low-pin-count packaged devices.

According to an embodiment, this important result may be obtained by realizing a packaged device with at least a novel input/output cell containing a common general purpose input/output circuit with a terminal coupled to a respective input/output connection pad of the device, the general purpose input/output circuit (GPIO) being adapted to be set in either a pull-up state or a pull-down state by an internal command of the integrated-circuit device, and including a configuring switch, for example a MOS switch controlled by a command, for coupling the terminal of the general purpose input/output circuit (GPIO) to the supply-distribution metal path.

Therefore, it may be possible to reduce voltage drops on a supply-distribution metal path of a device having the above architecture by setting either in a pull-up or pull-down state the general purpose input/output circuit, by coupling the respective input/output connection pad of the device either to an external power-supply line or to a ground node of the device, respectively, and by setting in a conduction state the controlled switch.

### BRIEF DESCRIPTION OF THE DRAWINGS

FIG. 1 depicts basically a classic packaged integrated device with a single supply pad, a corolla of input/output cells, and the supply-voltage reduction along the distribution metal path.

FIG. 2 depicts basically an embodiment of a packaged integrated device with a single supply pad and an embodiment of a general-purpose auxiliary supply input/output cell GPASIO.

FIG. 3 shows the packaged integrated device of FIG. 2 with the equivalent circuit of the supply metal ring when the switch of the novel general purpose auxiliary supply input/output cell GPASIO is on according to an embodiment.

FIG. 4 is the equivalent circuit of a supply metal ring highlighting the resistances between the supply pad and a spot on the supply metal ring when the switch of the novel general purpose auxiliary supply input/output cell GPASIO is on according to an embodiment.

### DETAILED DESCRIPTION

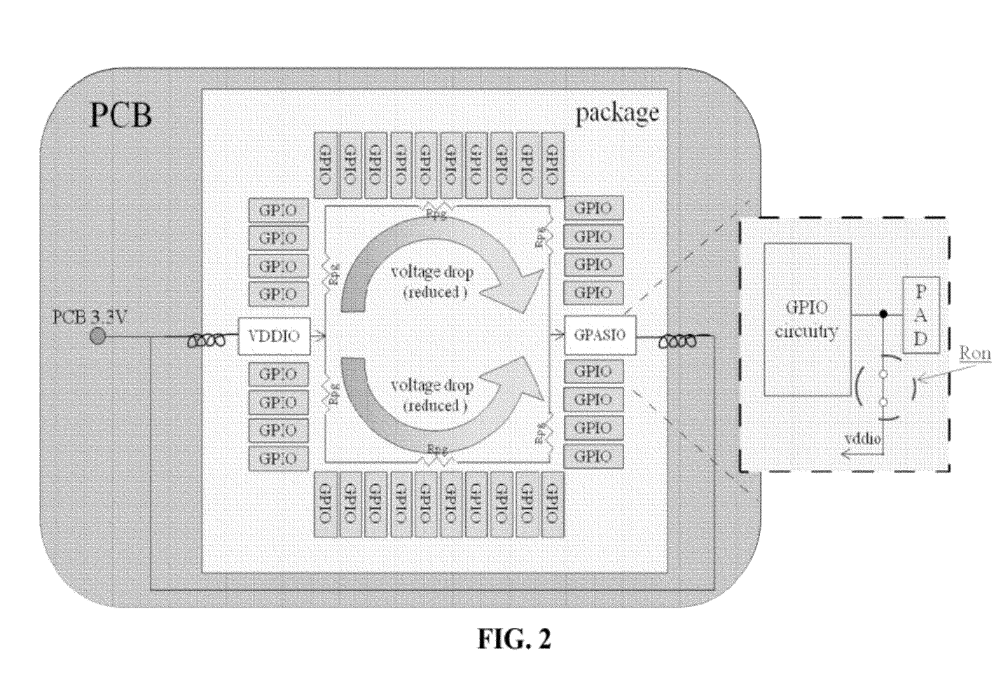

A basic embodiment of a packaged device, for example, a low-pin-count device, with general-purpose input/output cells according to an embodiment is shown in FIG. 2. The general-purpose input/output cells, herein referred to as general-purpose-auxiliary-supply input/output cell (GPASIO), substantially include a classic general purpose input/output circuit GPIO coupled to a respective pad and a controllable switch that couples the pad to the internal supply metal ring.

The controllable switch may be, for example, a MOS transistor controlled by a command generated by a core circuitry of the device.

When the switch is open, the GPASIO works as a common GPIO circuit. By closing the switch, setting the GPIO in a pull-up state, and by coupling the respective package pin to an external supply line, an auxiliary current is injected into the supply metal ring.

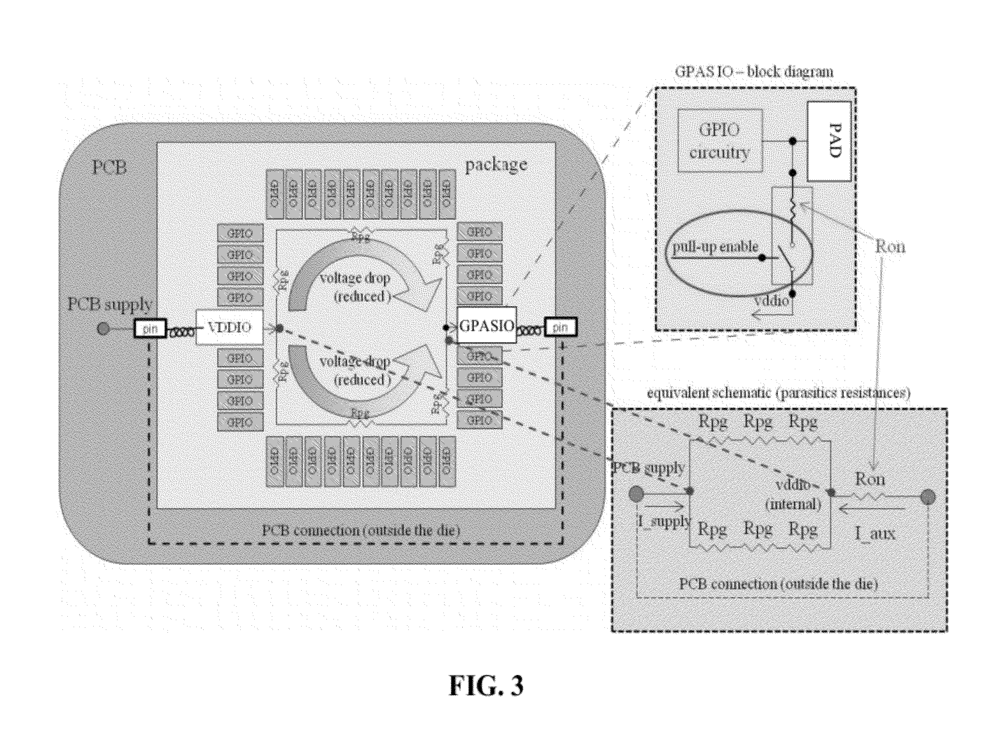

An equivalent electrical scheme of a packaged device, equipped with an embodiment of a GPASIO cell, for example, diametrically opposite to the supply pad of the device VDDIO, is shown in FIG. 3. By turning on the switch through an internally generated command PULL-UP ENABLE of the core circuitry of the device, and by setting in a pull-up state the GPIO circuit, the respective pin may be used as an auxiliary supply pin to deliver an additional current I_aux to the internal supply metal ring, thus reducing the voltage drop seen by any circuit or GPIO circuit coupled to the supply ring.

In an embodiment, this result is obtained at the cost of reducing the overall number of pins of the packaged device usable as input/output of signals, but this limitation is overwhelmed by the advantage of realizing a single type of packaged device, relieved of design constraints of prior-art low-pin-count packaged devices, in which the number of supply pads and of input/output signal pads is determined by users according to customer specifications.

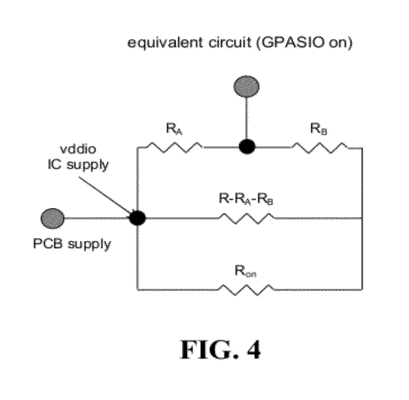

The smaller the on resistance of the switch (R_{ON}) of the GPASIO cell, the higher the current that can be injected through the circuit, and so the smaller the voltage drop in correspondence of any GPIO circuit or other circuit coupled to the internal supply metal ring. Referring to FIG. 4, when the switch is on, the resistance seen between the supply pad VDDIO and a generic point of the supply metal ring is

R_{A}//[R_{B}+((R−R_{A}−R_{B})//R_{ON})] (1)

wherein R_{A} is the resistance of the portion of the metal supply ring not contacting the GPASIO cell between the supply pad VDDIO and the considered generic point, R is the resistance of the whole supply ring, and R_{B} is the resistance of the portion of the metal supply ring not contacting the supply pad VDDIO between the GPASIO cell and the considered generic point. When the switch is off and current is provided to the internal supply metal ring only through the supply pad VDDIO, the resistance seen between the supply pad VDDIO and the considered generic point is

R_{A}//(R−R_{A}) (2)

which is always greater than the resistance given in the formula (1).

An embodiment of such a device may be realized in any fabrication technology, for example in bipolar technology, BCD, MOS, etc. In the so-called CMOSF9 fabrication technology, it is possible to realize controllable switches with a relatively small resistance R_{ON} with a maximum increase of area occupation of about 50% of the GPASIO compared to a GPIO cell, and without any bonding operation during the fabrication process of the device.

An embodiment of a low-pin-count device may have any number of GPASIO cells that may function as signal inputs/outputs or, when not in use as general purpose IO, as auxiliary supply inputs depending on application requirements.

The “auxiliary supply” feature of the GPASIO cell can be set at any time by, for example, core firmware, by software, or even statically by a hardware connection (tying) during the product design. Indeed, almost all GPIO circuits embedded in today's ICs, such as, for example, those present on the STM32xx microcontroller family disclosed on page 2 of the article by Tom Cantrell, “More than a core”, Circuit Cellar, Issue 213, April 2008, pages 80-86, which is incorporated by reference and which is freely downloadable from the following website:

http://www.st.com/internet/com/TECHNICAL_RESOURCES/TECHNICAL_LITERATURE/TECHNICAL_ARTICLE/1206952355.pdf or in the datasheet of the devices STM32F100x of STMicroelectronics, paragraph 2.21, downloadable from the following website:

http://www.st.com/internet/com/TECHNICAL_RESOURCES/TECHNICAL_LITERATURE/DATASHEET/CD00251732.pdf

are already adapted to be set in input pull-up/down state by the core circuit of the device. Therefore, if more than one supply pad is needed, users have only to couple one (or more) input/output signal pad(s) of a GPASIO cell to a supply line of the printed circuit board on which the packaged device is installed and to configure the GPASIO cell accordingly.

With an embodiment of such an architecture, a same packaged device is adapted to be used in both applications in which a single supply pad is insufficient or when a single supply pad is sufficient and a relatively large number of signal input/output pads is requested. This permits using a single architecture of packaged device for many different applications, instead of producing various packaged devices with different pad-ring configurations or bonding options, that means different packages, and thus several product codes (that should be qualified).

An embodiment of the disclosed GPASIO cells may also be configured for grounding a metal path, in order to prevent or minimize “bounces” of the ground potential along a metal path. Even if this disclosure refers to the case in which the GPASIO cell is to be coupled to a supply line of the device, the same observations made hereinbefore hold mutatis mutandis when the GPASIO cell is to be coupled to a ground node of the device.

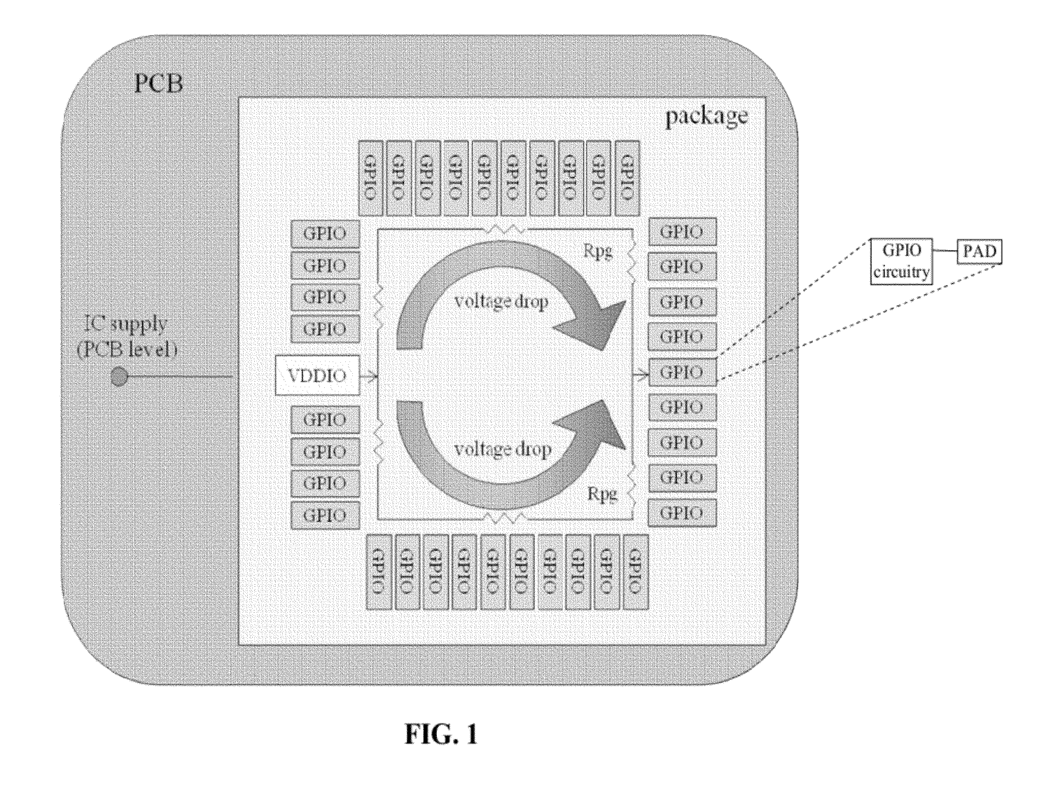

Possible modifications and/or additions may be made to the hereinabove disclosed and illustrated embodiment(s). For example, an embodiment of a device such as shown in FIGS. 1-4 may be, or may be part of, an integrated circuit, which may be coupled to one or more other integrated circuits to form a system such as a computer system, automobile control system, or smart phone. For example, at least one of the integrated circuits may be a controller such as a processor, and the integrated circuits may be disposed on the same, or on respective, integrated-circuit dies.

From the foregoing it will be appreciated that, although specific embodiments have been described herein for purposes of illustration, various modifications may be made without deviating from the spirit and scope of the disclosure. Furthermore, where an alternative is disclosed for a particular embodiment, this alternative may also apply to other embodiments even if not specifically stated.

1.-4. (canceled)

5. An integrated circuit, comprising:
a first supply conductor;
a first pad coupled to the supply conductor;
a second pad; and
a first selection circuit configurable to couple the second pad to the supply conductor.

6. The integrated circuit of claim 5, further including:
a perimeter region; and
wherein the supply conductor is disposed along at least a portion of the permiter region.

7. The integrated circuit of claim 5 wherein the supply conductor includes a metal.

8. The integrated circuit of claim 5, further including a intercoupling conductor extending from the first pad to the supply conductor.

9. The integrated circuit of claim 5, further including:
first and second opposite sides;
wherein the first pad is disposed on the first side; and
wherein the second pad is disposed on the second side.

10. The integrated circuit of claim 5 wherein the selection circuit is configurable in a supply configuration in which the selection circuit couples the second pad to the supply conductor.

11. The integrated circuit of claim 5 wherein the selection circuit includes a switch that is closable to couple the second pad to the supply conductor.

12. The integrated circuit of claim 5, further including:
an input/output circuit;
wherein the selection circuit is configurable in a supply configuration in which the selection circuit couples the second pad to the supply conductor; and
wherein the selection circuit is configurable in an input/output configuration in which the selection circuit couples the second pad to the input/output circuit.

13. The integrated circuit of claim 5 wherein the selection circuit is:
configurable to receive a control signal; and
configurable to couple the second pad to the supply conductor in response to the control signal.

14. The integrated circuit of claim 5 wherein the selection circuit:
is configurable to receive a control signal; and
includes a switch that is coupled between the supply conductor and the second pad and that is closable in response to the control signal.

15. The integrated circuit of claim 5, further including:
an input/output circuit; and
wherein the selection circuit is configurable:
to receive a control signal;
to couple the second pad to the supply conductor in response to the control signal having a supply value; and
to couple the second pad to the input/output circuit in response to the control signal having an input/output value.

16. The integrated circuit of claim 14 wherein the control signal includes an input/output pull-up signal.

17. The integrated circuit of claim 14 wherein the control signal includes an input/output pull-down signal.

18. The integrated circuit of claim 5, further including:
a second supply conductor;
a third pad coupled to the second supply conductor;
a fourth pad; and
a second selection circuit configurable to couple the fourth pad to the second supply conductor.

19. A system, comprising:
a first integrated circuit, including:
a first supply conductor;
a first pad coupled to the supply conductor;
a second pad; and
a first selection circuit configurable to couple the second pad to the supply conductor; and
a second integrated circuit coupled to the first integrated circuit.

20. The system of claim 19 wherein the first and second integrated circuits are disposed on a same integrated-circuit die.

21. The system of claim 19 wherein the first and second integrated circuits are disposed on respective integrated-circuit dies.

22. The system of claim 19 wherein one of the first and second integrated circuits includes a controller.

23. An integrated circuit, comprising:
a supply conductor;
a first pad configurable to couple a supply signal to the supply conductor;
a second pad; and
a selection circuit configurable to couple the second pad to the supply conductor.

24. A method, comprising:
coupling a supply signal from a first pad of an integrated circuit to a supply conductor of the integrated circuit; and
coupling the supply signal from a second pad of the integrated circuit to the supply conductor via a coupling circuit.

25. The method of claim 24, further including configuring the coupling circuit to couple the second pad to the supply conductor.

26. The method of claim 24, further including closing a switch that is coupled between the second pad and the supply conductor.

27. A method, comprising:
reducing an impedance between a first pad of an integrated circuit and a region of a supply conductor of the integrated circuit; and
receiving a supply signal with the first pad after reducing the impedance.

28. The method of claim 27 wherein reducing the impedance includes coupling a second pad of the integrated circuit to the supply conductor.

29. The method of claim 27 wherein reducing the impedance includes configuring a selection circuit to couple a second pad of the integrated circuit to the supply conductor.
